(19) United States
(12) Patent Application Publication
(10) Pub. No.: US 2017/0256497 A1
(43) Pub. Date: Sep. 7, 2017

(54) ELECTRONIC COMPONENT BUILT-IN SUBSTRATE AND METHOD FOR MANUFACTURING THE SAME

(71) Applicant: IBIDEN CO., LTD., Ogaki (JP)

(72) Inventors: Yasuhiko MANO, Ogaki (JP); Hiroyuki WATANABE, Ogaki (JP)

(73) Assignee: IBIDEN CO., LTD., Ogaki (JP)

(21) Appl. No.: 15/449,312

(22) Filed: Mar. 3, 2017

(30) Foreign Application Priority Data
Mar. 4, 2016 (JP) 2016-042435

(51) Int. Cl. H01L 23/538; H05K 3/46; H05K 1/11; H01L 21/48; H05K 1/18

(52) U.S. Cl. CPC H01L 23/5389; H01L 23/5383; H01L 21/4857; H01L 21/486; H01L 23/5384; H05K 1/183; H05K 1/115; H05K 3/4644

(57) ABSTRACT

An electronic component built-in substrate includes a first core layer having opening, a second core layer formed on the first core layer, a third core layer formed on the second core layer and having opening, a first electronic component accommodated in the opening of the first core layer, a second electronic component accommodated in the opening of the third core layer, and a first build-up structure formed on the first core layer on the opposite side of the second core layer such that the first build-up structure includes conductor layers and interlayer insulating layers, and a second build-up structure formed on the third core layer on the opposite side of the second core layer such that the second build-up structure includes conductor layers and interlayer insulating layers. The second core layer has rigidity which is higher than rigidity of the first core layer and rigidity of the third core layer.

### CROSS-REFERENCE TO RELATED APPLICATIONS

The present application is based upon and claims the benefit of priority to Japanese Patent Application No. 2016-042435, filed Mar. 4, 2016, the entire contents of which are incorporated herein by reference.

### BACKGROUND OF THE INVENTION

Field of the Invention

The present invention relates to an electronic component built-in wiring board and a method for manufacturing the electronic component built-in wiring board.

Description of Background Art

An electronic component built-in substrate may have an electronic component accommodated in an opening that penetrates a core substrate (for example, see Japanese Patent Laid-Open Publication No. 2015-2196). The entire contents of this publication are incorporated herein by reference.

### SUMMARY OF THE INVENTION

According to one aspect of the present invention, an electronic component built-in substrate includes a first core layer having an opening portion, a second core layer formed on the first core layer, a third core layer formed on the second core layer and having an opening portion, a first electronic component accommodated in the opening portion of the first core layer, a second electronic component accommodated in the opening portion of the third core layer, and a first outer side build-up structure formed on the first core layer on the opposite side with respect to the second core layer such that the first outer side build-up structure includes conductor layers and interlayer resin insulating layers, and a second outer side build-up structure formed on the third core layer on the opposite side with respect to the second core layer such that the second outer side build-up structure includes conductor layers and interlayer resin insulating layers. The second core layer has a rigidity which is higher than a rigidity of the first core layer and a rigidity of the third core layer.

According to another aspect of the present invention, a method for manufacturing an electronic component built-in substrate includes preparing a first intermediate base material including a first core layer, preparing a second intermediate base material including a second core layer, preparing a third intermediate base material including a third core layer, bonding the first, second and third intermediate base materials such that the first, second and third intermediate base materials form a laminated structure adhered through an adhesive layer formed between the first and second intermediate base materials and an adhesive layer formed between the second and third intermediate base materials, forming a first outer side build-up structure on the first core layer on the opposite side with respect to the second core layer such that the first outer side build-up structure includes conductor layers and interlayer resin insulating layers, and forming a second outer side build-up structure on the third core layer on the opposite side with respect to the second core layer such that the second outer side build-up structure includes conductor layers and interlayer resin insulating layers. The first intermediate base material includes the first core layer, a first electronic component accommodated in an opening portion of the first core layer, conductor layers formed on front and back surfaces of the first core layer respectively, interlayer resin insulating layers formed on the front and back surfaces of the first core layer respectively, and via conductor structures formed in the interlayer resin insulating layers and connected to electrode structures of the first electronic component respectively, the third intermediate base material includes the third core layer, a second electronic component accommodated in an opening portion of the third core layer, conductor layers formed on front and back surfaces of the third core layer respectively, interlayer resin insulating layers formed on the front and back surfaces of the third core layer respectively, and via conductor structures formed in the interlayer resin insulating layers and connected to electrode structures of the second electronic component respectively, and the second core layer has a rigidity which is higher than a rigidity of the first core layer and a rigidity of the third core layer.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1A describes a state in which an electronic component built-in substrate is used;

FIG. 1B is a cross-sectional view of the electronic component built-in substrate;

FIG. 2 is an enlarged cross-sectional view of a portion of the electronic component built-in substrate;

FIG. 3A is a perspective view of a capacitor component;

FIG. 3B is a cross-sectional view of the capacitor component;

FIG. 4A is a cross-sectional view of an inductor component;

FIG. 4B is a plan view of the inductor component;

FIG. 4C is a side view of the inductor component;

FIG. 5A is a cross-sectional view of a first intermediate base material;

FIG. 5B is a cross-sectional view of a second intermediate base material;

FIG. 5C is a cross-sectional view of a third intermediate base material;

FIG. 6A-6D illustrate manufacturing processes of the first intermediate base material;

FIG. 7A-7D illustrate manufacturing processes of the first intermediate base material;

FIG. 8A-8C illustrate manufacturing processes of the first intermediate base material;

FIGS. 9A and 9B illustrate manufacturing processes of the second intermediate base material;

FIG. 10A-10D illustrate manufacturing processes of the third intermediate base material;

FIG. 11A-11D illustrate manufacturing processes of the third intermediate base material;

FIG. 12A-12C illustrate manufacturing processes of the third intermediate base material;

FIG. 13 illustrates a manufacturing process of the electronic component built-in substrate;

FIGS. 14A and 14B illustrate manufacturing processes of the electronic component built-in substrate;

FIGS. 15A and 15B illustrate manufacturing processes of the electronic component built-in substrate;

FIGS. 16A and 16B illustrate manufacturing processes of the electronic component built-in substrate;

FIGS. 17A and 17B illustrate manufacturing processes of the electronic component built-in substrate;

FIG. 18 illustrates a manufacturing process of the electronic component built-in substrate;

FIG. 19 illustrates a manufacturing process of the electronic component built-in substrate;

FIG. 20 illustrates a manufacturing process of the electronic component built-in substrate;

FIG. 21 illustrates a manufacturing process of the electronic component built-in substrate; and

FIG. 22 illustrates a manufacturing process of the electronic component built-in substrate.

### DETAILED DESCRIPTION OF THE EMBODIMENTS

The embodiments will now be described with reference to the accompanying drawings, wherein like reference numerals designate corresponding or identical elements throughout the various drawings.

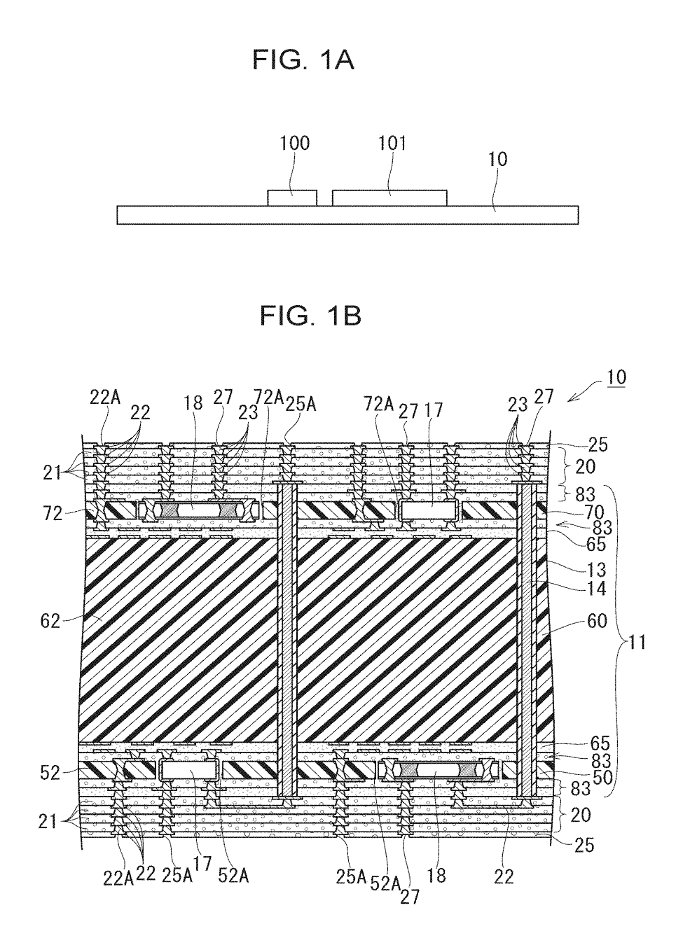

As illustrated in FIG. 1A, an electronic component built-in substrate 10 of the present embodiment is used, for example, for a semiconductor component. Electronic components such as a semiconductor element 101 (for example, an LSI) and a power supply element 100 (for example, a DC-DC converter) for driving the semiconductor element 101 are mounted on the electronic component built-in substrate 10. As illustrated in FIG. 1B, the electronic component built-in substrate 10 is structured to have outer side build-up parts 20 respectively on a front side (upper side in FIG. 1B) and a back side (lower side in FIG. 1B) of a core substrate 11.

As illustrated in FIG. 1B, in each of the outer side build-up parts 20, multiple interlayer resin insulating layers 21 and multiple conductor layers 22 are alternately laminated. Adjacent conductor layers (22, 22) are connected to each other by via conductors 23 formed in the interlayer resin insulating layers 21. The interlayer resin insulating layers 21, for example, are each formed by an insulating film for a build-up substrate (film containing 30-70% by weight of an inorganic filler as a reinforcing material in a thermosetting insulating resin).

A solder resist layer 25 is laminated on an outermost conductor layer (22A) formed on an outermost side (that is, a side farthest from the core substrate 11) of each of the outer side build-up parts 20. Openings (25A) are formed in the solder resist layer 25, and pads 27 are formed by portions of the outermost conductor layer (22A) that are respectively exposed by the openings (25A). The pads 27 formed on the front side of the electronic component built-in substrate 10 are connected to the power supply element 100 and the semiconductor element 101 (see FIG. 1A) as components mounted on the electronic component built-in substrate 10.

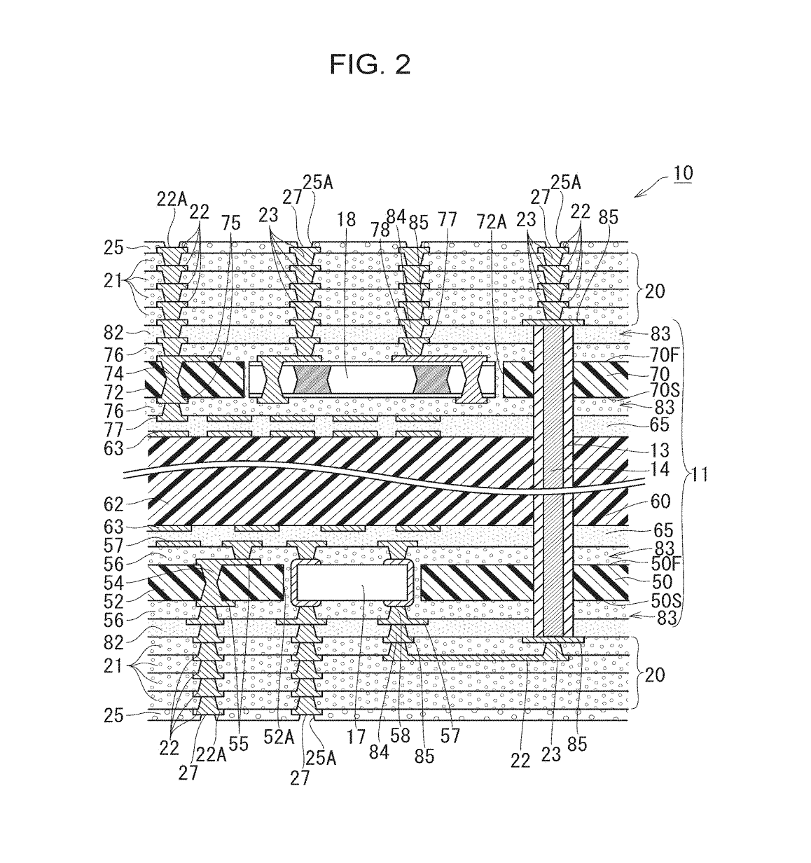

As illustrated in FIG. 2, the core substrate 11 includes a first core layer 50, a second core layer 60 and a third core layer 70 in an order from the back side. Inner side build-up parts 83 are respectively laminated on a front side surface and a back side surface of the first core layer 50 and a front side surface and a back side surface of the third core layer 70. The above-described outer side build-up parts 20 are respectively laminated on the inner side build-up part 83 formed on the back side of the first core layer 50 and the inner side build-up part 83 formed on the front side of the third core layer 70.

Adhesive layers 65 are respectively formed on the front side and the back side of the second core layer 60. Then, the inner side build-up part 83 formed on the front side of the first core layer 50 and the second core layer 60 are bonded to each other via the adhesive layer 65 formed on the back side of the second core layer 60, and the inner side build-up part 83 formed on the back side of the third core layer 70 and the second core layer 60 are bonded to each other via the adhesive layer 65 formed on the front side of the second core layer 60. The adhesive layers 65 are each formed from, for example, a prepreg (a resin sheet of a B-stage formed by impregnating a core material with a resin) or the above-described insulating film for a build-up substrate.

The first core layer 50 is formed by a first insulating base material 52. In the first insulating base material 52, multiple openings (52A) are formed penetrating the first insulating base material 52. In each of the openings (52A), a capacitor component 17 or an inductor component 18 as an electronic component is accommodated (FIG. 2 illustrates an example in which a capacitor component 17 is accommodated).

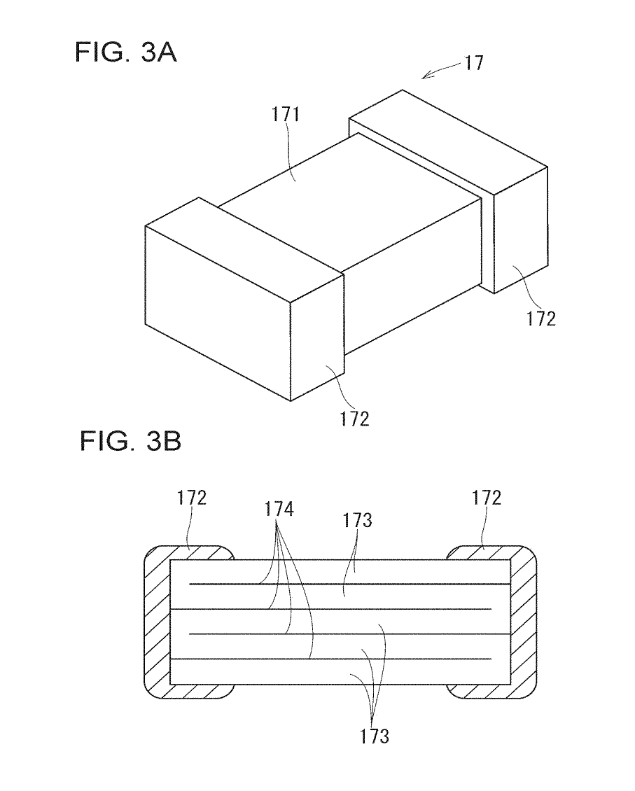

As illustrated in FIG. 3A, the capacitor component 17 includes a block-shaped element body 171 and metal film-like terminal electrodes (172, 172) that cover an outer surface of the element body 171. The element body 171 is formed by laminating multiple ceramic sheets 173 (see FIG. 3B). There are two types of the ceramic sheets 173, one having an internal electrode 174 formed on one side and the other not having an internal electrode 174 formed on one side.

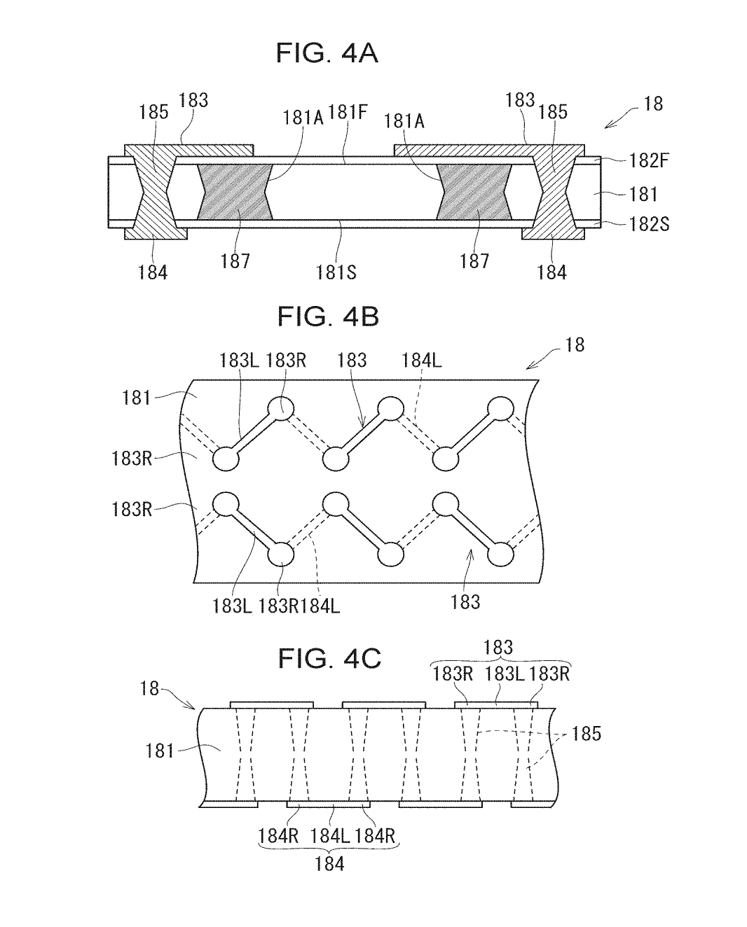

As illustrated in FIG. 4A, the inductor component 18 includes: a resin core base material 181 having magnetic bodies 187 respectively in openings (181A), the magnetic bodies 187 each containing a magnetic material; a first resin insulating layer (182F) formed on an F surface (181F), which is a front side surface of the core base material 181; a second resin insulating layer (182S) formed on an S surface (181S), which is a back side surface of the core base material 181; a first conductor layer 183 formed on the first resin insulating layer (182F); a second conductor layer 184 formed on the second resin insulating layer (182S); and multiple conductors 185 connecting the first conductor layer 183 and the second conductor layer 184.

As illustrated in FIGS. 4B and 4C, the first conductor layer 183 includes lands (183R) formed respectively right above the conductors 185, and connection patterns (183L) each connecting adjacent lands (183R, 183R). Similarly, the second conductor layer 184 includes lands (184R) formed respectively right above the conductors 185, and connection patterns (184L) each connecting adjacent lands (184R, 184R). The first conductor layer 183 and the second conductor layer 184 are formed in a helical shape (a spiral shape along an axis parallel to the front and back surfaces of the inductor component 18) via the conductors 185.

As illustrated in FIG. 2, conductor layers 55 of predetermined patterns are respectively formed on an F surface (50 F), which is the front side surface of the first core layer 50, and an S surface (50S), which is the back side surface of the first core layer 50. Interlayer resin insulating layers 56 are respectively laminated on the front and back conductor layers 55. Conductor layers 57 of predetermined patterns are respectively laminated on the interlayer resin insulating layers 56. Further, via conductors 58 are formed in the interlayer resin insulating layers 56. Then, due to the via conductors 58, the conductor layers 55 are respectively connected to the conductor layer 57, and, the electrodes of the capacitor components 17 or inductor components 18 (FIG. 2 illustrates an example of a capacitor component 17) that are respectively accommodated in the openings (52A) are connected to the conductor layers 57. The interlayer resin insulating layer 56 and the conductor layer 57 on the F surface (50F) side form the inner side build-up part 83 positioned on the front side of the first core layer 50.

An interlayer resin insulating layer 82 is laminated on the conductor layer 57 on the S surface (50S) side of the first core layer 50. A conductor layer 85 is laminated on the interlayer resin insulating layer 82. Further, via conductors 84 are formed in the interlayer resin insulating layers 82. Then, due to the via conductors 84, the conductor layer 57 and the conductor layer 85 are connected to each other. The interlayer resin insulating layers (56, 82) and the conductor layers (57, 85) on the S surface (50S) side form the inner side build-up part 83 positioned on the back side of the first core layer 50.

The third core layer 70 is formed by a third insulating base material 72. In the third insulating base material 72, multiple openings (72A) are formed penetrating the third insulating base material 72. In each of the openings (72A), a capacitor component 17 or an inductor component 18 as an electronic component is accommodated (FIG. 2 illustrates an example in which an inductor component 18 is accommodated).

Conductor layers 75 of predetermined patterns are respectively formed on an F surface (70F), which is the front side surface of the third core layer 70, and an S surface (70S), which is the back side surface of the third core layer 70. Interlayer resin insulating layers 76 are respectively laminated on the front and back conductor layers 75. Conductor layers 77 of predetermined patterns are respectively laminated on the interlayer resin insulating layers 76. Further, via conductors 78 are formed in the interlayer resin insulating layers 76. Then, due to the via conductors 78, the conductor layers 75 are respectively connected to the conductor layer 77, and, the electrodes of the capacitor components 17 or inductor components 18 (FIG. 2 illustrates an example of an inductor component 18) that are respectively accommodated in the openings (72A) are connected to the conductor layers 77. The interlayer resin insulating layer 76 and the conductor layer 77 on the S surface (70S) side form the inner side build-up part 83 positioned on the back side of the third core layer 70.

An interlayer resin insulating layer 82 is laminated on the conductor layer 77 on the F surface (70F) side of the third core layer 70. A conductor layer 85 is laminated on the interlayer resin insulating layer 82. Further, via conductors 84 are formed in the interlayer resin insulating layers 82. Then, due to the via conductors 84, the conductor layer 77 and the conductor layer 85 are connected to each other. The interlayer resin insulating layers (76, 82) and the conductor layers (77, 85) on the F surface (70F) side form the inner side build-up part 83 positioned on the front side of the third core layer 70.

The second core layer 60 is formed by a second insulating base material 62. Different from the above-described first insulating base material 52 and third insulating base material 72, the second insulating base material 62 does not have openings for accommodating electronic components. The second core layer 60 has a higher rigidity than the first core layer 50 and the third core layer 70. Specifically, a thickness (for example, about 800 μm) of the second core layer 60 is 1.5 or more times larger with respect to a thickness (for example, about 400 μm) of the first core layer 50 and a thickness (for example, about 400 μm) of the third core layer. Further, in addition to increasing the thickness of the second core layer 60, it is also possible to increase the rigidity of the second core layer 60 by allowing a material that forms the second core layer 60 to be different from materials that form the first core layer 50 and the third core layer 70. Specifically, for example, it is possible to change a thickness or the number of sheets of glass cloth as a reinforcing material contained in the core layer or to change molecular weight of the thermosetting resin contained in the core layer. It is also possible that the second core layer 60 is formed by a multilayer core in which multiple second insulating base materials 62 are laminated via adhesive layers.

Conductor layers 63 of predetermined patterns are respectively formed on a front side surface and a back side surface of the second core layer 60. The above-described adhesive layers 65 are respectively on the front side and back side conductor layers 63. The back side adhesive layer 65 is laminated on the conductor layer 57 on the F surface (50F) side of the first core layer 50. The back side adhesive layer 65 is filled between adjacent portions of the conductor layer 63 formed on the back side of the second core layer 60 and is also filled between adjacent portions of the conductor layer 57 formed on the F surface (50F) side of the first core layer 50. Further, the conductor layer 77 on the S surface (70S) of the third core layer 70 is laminated on the front side adhesive layer 65. The front side adhesive layer 65 is filled between adjacent portions of the conductor layer 63 formed on the front side of the second core layer 60 and is also filled between adjacent portions of the conductor layer 77 formed on the S surface (70S) side of the third core layer 70.

The conductor layer 85 contained in the inner side build-up part 83 formed on the back side of the first core layer 50 and the conductor layer 85 contained in the inner side build-up part 83 formed on the front side of the third core layer 70 are connected by through-hole conductors 13 that penetrate the core substrate 11. The through-hole conductors 13 are formed by forming, for example, copper plating on wall surfaces of through holes (13A) that penetrate the core substrate 11. Inner sides of the through-hole conductors 13 are filled with non-conductive filler 14.

The through-hole conductors 13 are connected, via the conductor layers 22 contained in the outer side build-up part 20 formed on the back side of the core substrate 11, to the electronic components (a capacitor component 17 in the example of FIG. 2) accommodated in the openings (52A) of the first core layer 50. Specifically, as illustrated in FIG. 2, an electrode formed on the back side of the capacitor component 17 accommodated in the first core layer 50 is connected via conductors (23, 58, 84) to a conductor layer 22, and this conductor layer 22 is connected via another via conductor 23 to a portion of the conductor layer 85 formed a back side of a through-hole conductor 13.

Further, the through-hole conductors 13 are connected to the pads 27 formed on the front side of the electronic component built-in substrate 10. As a result, the electronic components accommodated in the openings (52A) of the first core layer 50 are electrically connected to an electronic component mounted on the electronic component built-in substrate 10. Specifically, the multiple conductor layers 22 contained in the outer side build-up part 20 formed on the front side of the core substrate 11 are formed to be stacked on the through-hole conductors 13, and the conductor layer 85 formed on the front side of the through-hole conductors 13 and the multiple conductor layers 22 are connected via the multiple via conductors 23. The multiple via conductors 23 that connect the conductor layer 85 on the through-hole conductors 13 and the multiple conductor layers 22 form stack vias that are linearly formed in a thickness direction of the electronic component built-in substrate 10.

The electronic components accommodated in the openings (72A) of the third core layer 70 are connected to the pads 27 formed on the front side of the electronic component built-in substrate 10. As a result, the electronic components accommodated in the third core layer 70 are electrically connected to an electronic component mounted on the electronic component built-in substrate 10. Specifically, as illustrated in FIG. 2, electrodes formed on the front side of the inductor component 18 accommodated in the third core layer 70 are connected via the via conductors (78, 84) to the front side conductor layer 85 of the core substrate 11. Further, the multiple conductor layers 22 contained in the outer side build-up part 20 formed on the front side of the core substrate 11 are formed to be stacked on the conductor layer 85 that is connected to the electrodes of the inductor component 18, and the conductor layer 85 and the multiple conductor layers 22 are connected to each other via the multiple via conductors 23. The multiple via conductors 23 that are connected to the electrodes of the inductor component 18 form stack vias that are linearly formed in the thickness direction of the electronic component built-in substrate 10.

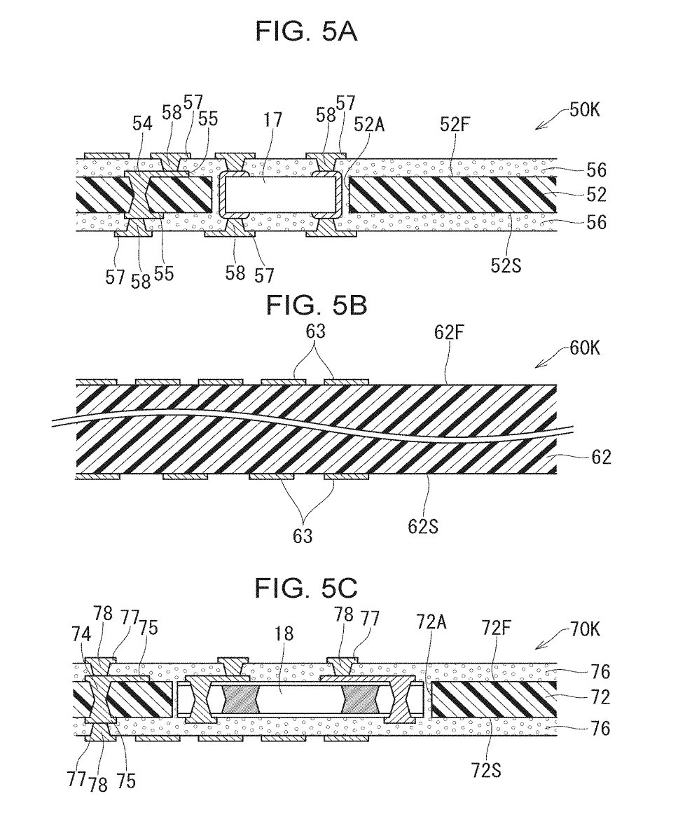

Next, a method for manufacturing the electronic component built-in substrate 10 of the present embodiment is described. Here, the electronic component built-in substrate 10 is manufactured using a first intermediate base material (50K) illustrated in FIG. 5A, a second intermediate base material (60K) illustrated in FIG. 5B, and a third intermediate base material (70K) illustrated in FIG. 5C. Therefore, first, methods for manufacturing the first intermediate base material (50K), the second intermediate base material (60K) and the third intermediate base material (70K) are described in the following A-C.

A. Method for Manufacturing First Intermediate Base Material (50K)

The first intermediate base material (50K) may be manufactured using a method, for example, described in International Publication No. 2013/008552. The entire contents of this publication are incorporated herein by reference. Specifically, the first intermediate base material (50K) is manufactured as follows.

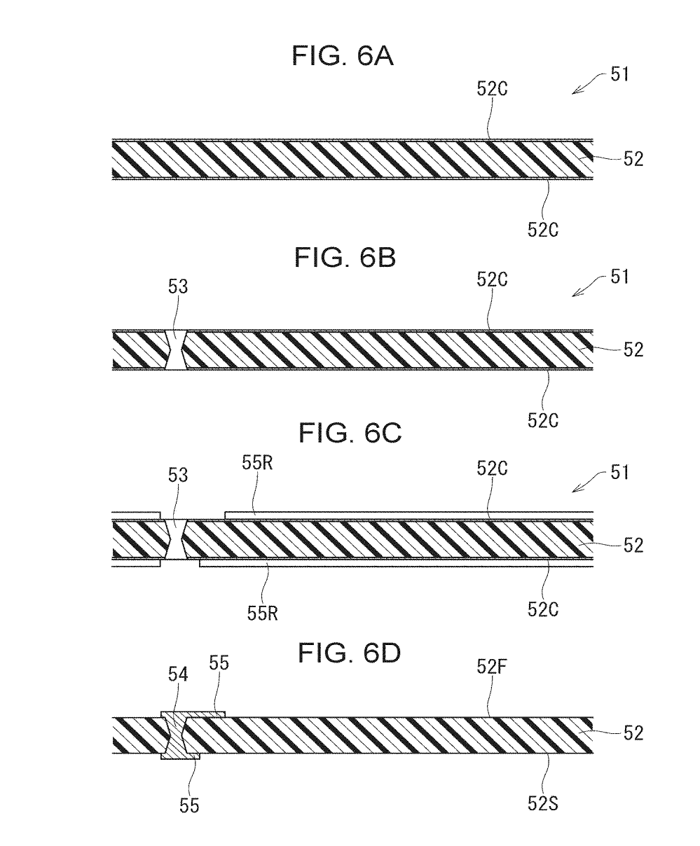

A1. A first copper-clad laminated plate 51 obtained by laminating a copper foil (52C) on both front side and back side surfaces of the first insulating base material 52 is prepared (see FIG. 6A).

A2. An electrical conduction through hole 53 penetrating the first copper-clad laminated plate 51 is formed by laser processing (see FIG. 6B), and an electroless plating film (not illustrated in the drawings) is formed on the copper foil (52C) and on an inner surface of the electrical conduction through hole 53 by an electroless plating treatment. Next, a plating resist (55R) of a predetermined pattern is formed on the electroless plating film on the copper foil (52C) (see FIG. 6C).

A3. An electrolytic plating treatment is performed. The electrical conduction through hole 53 is filled with the electrolytic plating and a conductor 54 is formed, and an electrolytic plating film (not illustrated in the drawings) is formed in a non-forming portion of the plating resist (55R) on the electroless plating film (not illustrated in the drawings) on the copper foil (52C). Next, the plating resist (55R) is peeled off, and the electroless plating film (not illustrated in the drawings) and the copper foil (52C) under the plating resist (55R) are removed. Then, the conductor layers 55 are respectively formed on an F surface (52F), which is the front side surface of the first insulating base material 52, and an S surface (52S), which is the back side surface of the first insulating base material 52, from the copper foil (52C), the electroless plating film and the electrolytic plating film, and the front side conductor layer 55 and the back side conductor layer 55 are connected by the conductor 54 (see FIG. 6D).

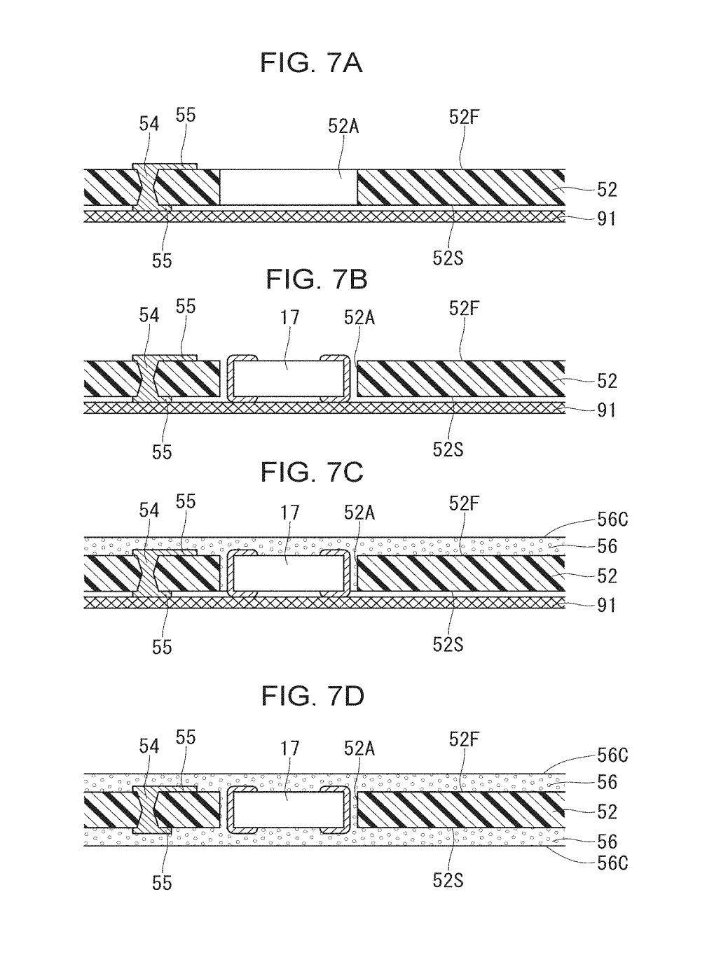

A4. An opening (52A) penetrating the first insulating base material 52 is formed by router processing or laser processing, and a tape 91 formed of a PET film is affixed to the S surface (52S) of the first insulating base material 52 so as to close the opening (52A) (see FIG. 7A). Then, a capacitor component 17 is accommodated in the opening (52A) by a mounter (not illustrated in the drawings) (see FIG. 7B).

A5. On the conductor layer 55 on the F surface (52F) of the first insulating base material 52, an insulating film for a build-up substrate as an interlayer resin insulating layer 56 and a copper foil (56C) are laminated, and then the resulting substrate is hot-pressed. In this case, the insulating film for a build-up substrate is filled between portions of the conductor layer 55 on the F surface (52F) of the first insulating base material 52, and a thermosetting resin of the insulating film for a build-up substrate is filled in a gap between an inner surface of the opening (52A) and the capacitor component 17 (see FIG. 7C).

A6. The tape 91 is removed. On the conductor layer 55 on the S surface (52S) of the first insulating base material 52, an insulating film for a build-up substrate as an interlayer resin insulating layer 56 and a copper foil (56C) are laminated, and then the resulting substrate is hot-pressed. In this case, the insulating film for a build-up substrate is filled between portions of the conductor layer 55 on the S surface (52S) of the first insulating base material 52, and a thermosetting resin of the insulating film for a build-up substrate is filled in the gap between the inner surface of the opening (52A) and the capacitor component 17 (see FIG. 7D).

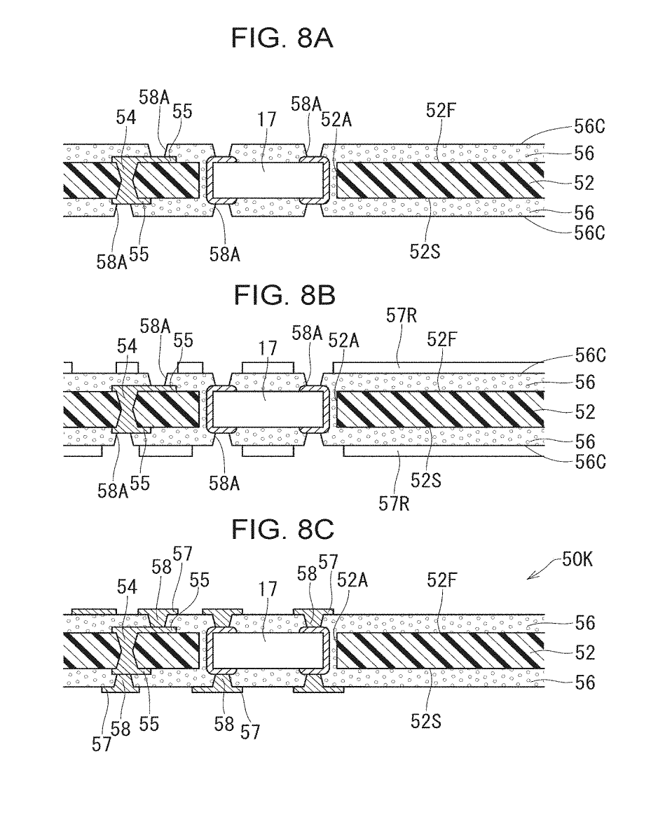

A7. Multiple via holes (58A) are formed by irradiating CO2 laser to the front side and back side interlayer resin insulating layers (56, 56). Some of the multiple via holes (58A) are formed on the conductor layers 55, and some other via holes (58A) are formed on the electrodes of the capacitor component 17 (see FIG. 8A). Next, an electroless plating film (not illustrated in the drawings) is formed on the copper foil (56C) and on inner surfaces of the via holes (58A) by an electroless plating treatment, and a plating resist (57R) of a predetermined pattern is formed on the electroless plating film on the copper foil (56C) (see FIG. 8B).

A8. An electrolytic plating treatment is performed. The via holes (58A) are filled with the electrolytic plating and the via conductors 58 are formed, and an electrolytic plating film (not illustrated in the drawings) is formed in a non-forming portion of the plating resist (57R) on the electroless plating film (not illustrated in the drawings) on the copper foil (56C). Next, the plating resist (57R) is peeled off, and the electroless plating film (not illustrated in the drawings) and the copper foil (56C) under the plating resist (57R) are removed. Then, conductor layers 57 are respectively formed on the front side and back side interlayer resin insulating layers 56 of the first insulating base material 52 from the copper foil (56C), the electroless plating film and the electrolytic plating film, and some portions of the conductor layers 57 and the conductor layers 55 are connected by some of the via conductors 58, and the other portions of the conductor layers 57 and the electrodes of the capacitor component 17 are connected by the other via conductors 58 (see FIG. 8C). As a result, the first intermediate base material (50K) illustrated in FIG. 5A is obtained.

B. Method for Manufacturing Second Intermediate Base Material (60K)

The second intermediate base material (60K) is manufactured as follows.

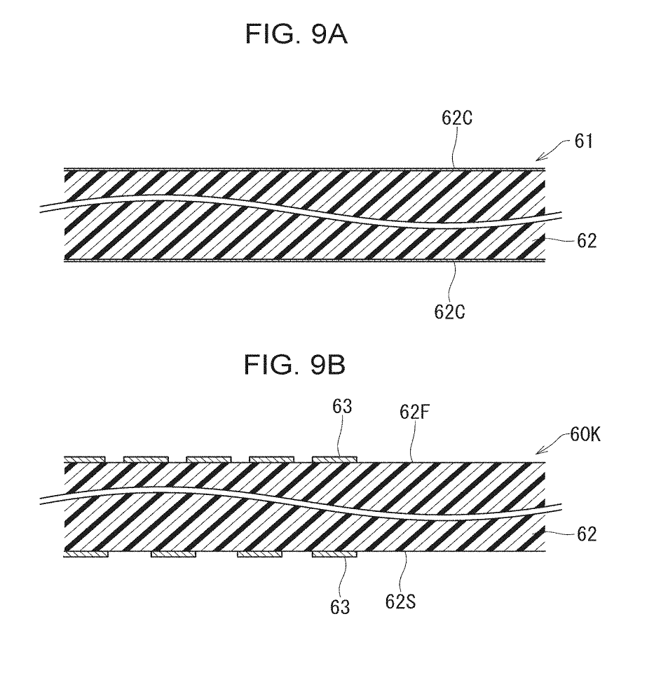

B1. A second copper-clad laminated plate 61 obtained by laminating a copper foil (62C) on both front side and back side surfaces of the second insulating base material 62 is prepared (see FIG. 9A).

B2. The front side and back side surfaces of the second copper-clad laminated plate 61 are subjected to an electroless plating treatment and an electrolytic plating treatment, and an electroless plating film and an electrolytic plating film are formed on the copper foil (62C). Next, an etching resist of a predetermined pattern (not illustrated in the drawings) is formed on the electrolytic plating film. Next, the electrolytic plating film, the electroless plating film and the copper foil (62C) in a non-forming portion of the etching resist are removed using an etching solution. Then, the conductor layers 63 are respectively formed on an F surface (62F), which is the front side surface of the second insulating base material 62, and S surface (62S), which is the back side surface of the second insulating base material 62, from the copper foil (62C), the electroless plating film and the electrolytic plating film (see FIG. 9B). As a result, the second intermediate base material (60K) illustrated in FIG. 5B is obtained.

C. Method for Manufacturing Third Intermediate Base Material (70K)

The third intermediate base material (70K) is manufactured using the same method as the above-described method for manufacturing the first intermediate base material (50K). Specifically, the third intermediate base material (70K) is manufactured as follows.

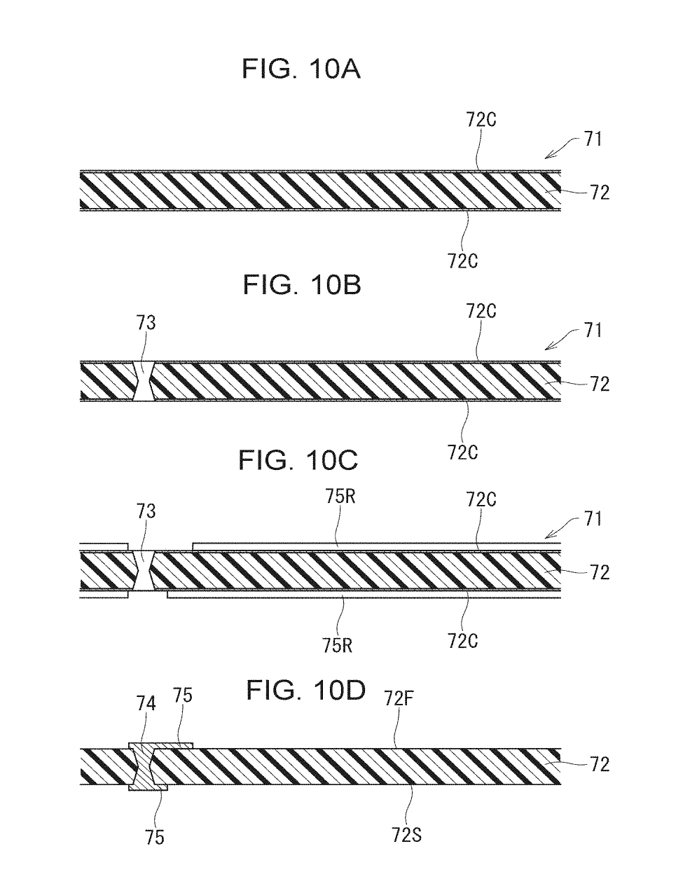

C1. A third copper-clad laminated plate 71 obtained by laminating a copper foil (72C) on both front side and back side surfaces of the third insulating base material 72 is prepared (see FIG. 10A).

C2. An electrical conduction through hole 73 penetrating the third copper-clad laminated plate 71 is formed by laser processing (see FIG. 10B), and an electroless plating film (not illustrated in the drawings) is formed on the copper foil (72C) and on an inner surface of the electrical conduction through hole 73 by an electroless plating treatment, and a plating resist (75R) of a predetermined pattern is formed on the electroless plating film on the copper foil (72C) (see FIG. 10C).

C3. An electrolytic plating treatment is performed. The electrical conduction through hole 73 is filled with the electrolytic plating and a conductor 74 is formed, and an electrolytic plating film (not illustrated in the drawings) is formed in a non-forming portion of the plating resist (75R) on the electroless plating film (not illustrated in the drawings) on the copper foil (72C). Next, the plating resist (75R) is peeled off, and the electroless plating film (not illustrated in the drawings) and the copper foil (72C) under the plating resist (75R) are removed. Then, the conductor layers 75 are respectively formed on an F surface (72F), which is the front side surface of the third insulating base material 72, and an S surface (72S), which is the back side surface of the third insulating base material 72, from the copper foil (72C), the electroless plating film and the electrolytic plating film, and the front side conductor layer 75 and the back side conductor layer 75 are connected by the conductor 74 (see FIG. 10D).

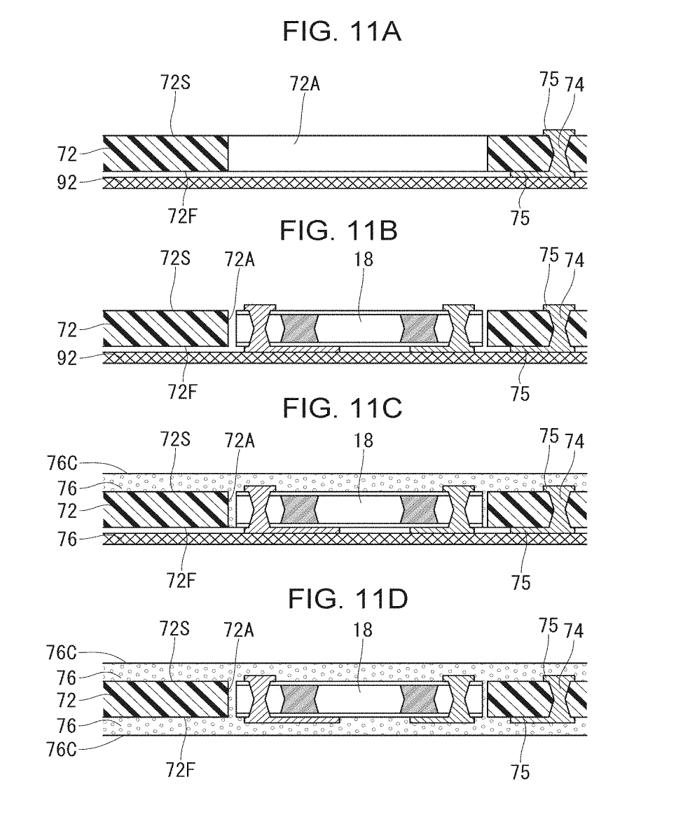

C4. An opening (72A) penetrating the third insulating base material 72 is formed by router processing or laser processing, and a tape 92 formed of a PET film is affixed to the F surface (72F), which is the front side surface of the third insulating base material 72 so as to close the opening (72A) (see FIG. 11A). Then, an inductor component 18 is accommodated in the opening (72A) by a mounter (not illustrated in the drawings) (see FIG. 11B). The inductor component 18 may be obtained using a method, for example, described in Japanese Patent Laid-Open Publication No. 2014-116465. The entire contents of this publication are incorporated herein by reference.

C5. On the conductor layer 75 on the S surface (72S), which is the back side surface of the third insulating base material 72, an insulating film for a build-up substrate as an interlayer resin insulating layer 76, and a copper foil (76C) are laminated, and then the resulting substrate is hot-pressed. In this case, the insulating film for a build-up substrate is filled between portions of the conductor layer 75 on the S surface (72S) of the third insulating base material 72, and a thermosetting resin of the insulating film for a build-up substrate is filled in a gap between an inner surface of the opening (72A) and the inductor component 18 (see FIG. 11C).

C6. The tape 92 is removed. On the conductor layer 75 on the F surface (72F) of the third insulating base material 72, an insulating film for a build-up substrate as an interlayer resin insulating layer 76 and a copper foil (76C) are laminated, and then the resulting substrate is hot-pressed. In this case, the insulating film for a build-up substrate is filled between portions of the conductor layer 75 on the F surface (72F) of the third insulating base material 72, and a thermosetting resin of the insulating film for a build-up substrate is filled in the gap between the inner surface of the opening (72A) and the inductor component 18 (see FIG. 11D).

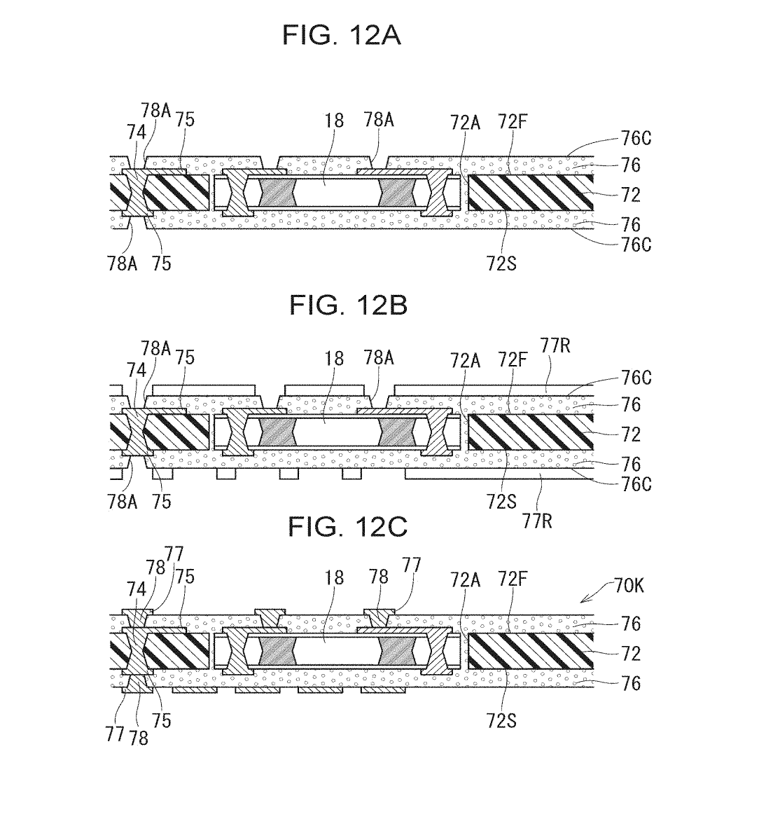

C7. Multiple via holes (78A) are formed by irradiating CO2 laser to the front side and back side interlayer resin insulating layers 76, 76. Some of the multiple via holes (78A) are formed on the conductor layers 75, and some other via holes (78A) are formed on the electrodes of the inductor component 18 (see FIG. 12A). Next, an electroless plating film (not illustrated in the drawings) is formed on the copper foil (76C) and on inner surfaces of the via holes (78A) by an electroless plating treatment, and a plating resist (77R) of a predetermined pattern is formed on the electroless plating film on the copper foil (76C) (see FIG. 12B).

C8. An electrolytic plating treatment is performed. The via holes (78A) are filled with the electrolytic plating and the via conductors 78 are formed, and an electrolytic plating film (not illustrated in the drawings) is formed in a non-forming portion of the plating resist (77R) on the electroless plating film (not illustrated in the drawings) on the copper foil (76C). Next, the plating resist (77R) is peeled off, and the electroless plating film (not illustrated in the drawings) and the copper foil (76C) under the plating resist (77R) are removed. Then, conductor layers 77 are respectively formed on the front side and back side interlayer resin insulating layers 66 of the third insulating base material 72 from the copper foil (76C), the electroless plating film and the electrolytic plating film, and some portions of the conductor layers 77 and the conductor layers 75 are connected by some of the via conductors 78, and the other portions of the conductor layers 77 and the electrodes of the inductor component 18 are connected by the other via conductors 78 (see FIG. 12C). As a result, the third intermediate base material (70K) illustrated in FIG. 5C is obtained.

The above is the description for the methods for manufacturing the first intermediate base material (50K), the second intermediate base material (60K) and the third intermediate base material (70K). Next, a method for manufacturing the electronic component built-in substrate 10 using the first intermediate base material (50K), the second intermediate base material (60K) and the third intermediate base material (70K) is described.

The electronic component built-in substrate 10 is manufactured as follows.

(1) An alignment mark (not illustrated in the drawings) is formed in the first intermediate base material (50K), the second intermediate base material (60K) and the third intermediate base material (70K) [symbol] An example of the alignment mark is a pin hole penetrating the intermediate base materials (50K, 60K, 70K).

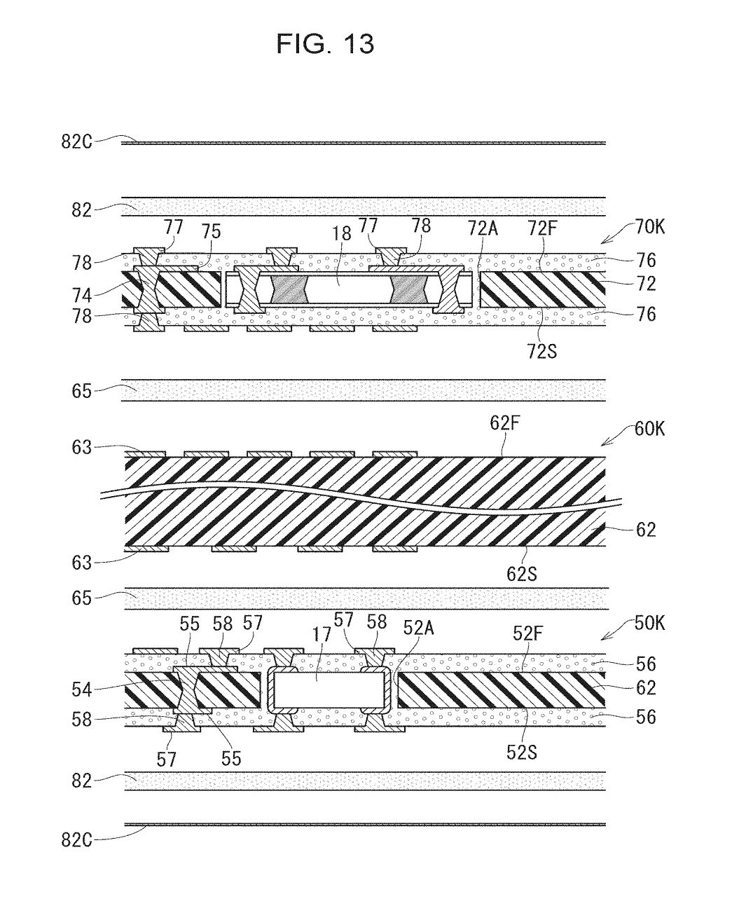

(2) The second intermediate base material (60K) is overlaid on the front side of the first intermediate base material (50K), and the third intermediate base material (70K) is overlaid on the front side of the second intermediate base material (60K) (see FIG. 13). In this case, a prepreg as an interlayer resin insulating layer 82 and a copper foil (82C) are overlaid in this order on the back side of the first intermediate base material (50K), and an insulating film for a build-up substrate as an interlayer resin insulating layer 82 and a copper foil (82C) are overlaid in this order on the front side of the third intermediate base material (70K). Further, prepregs as the adhesive layers 65 are respectively formed between the first intermediate base material (50K) and the second intermediate base material (60K) and between the second intermediate base material (60K) and the third intermediate base material (70K). Positions of the first intermediate base material (50K), the second intermediate base material (60K) and the third intermediate base material (70K) in a horizontal direction are determined with reference to the alignment mark. For each of the adhesive layers 65, an insulating film for a build-up substrate may be used.

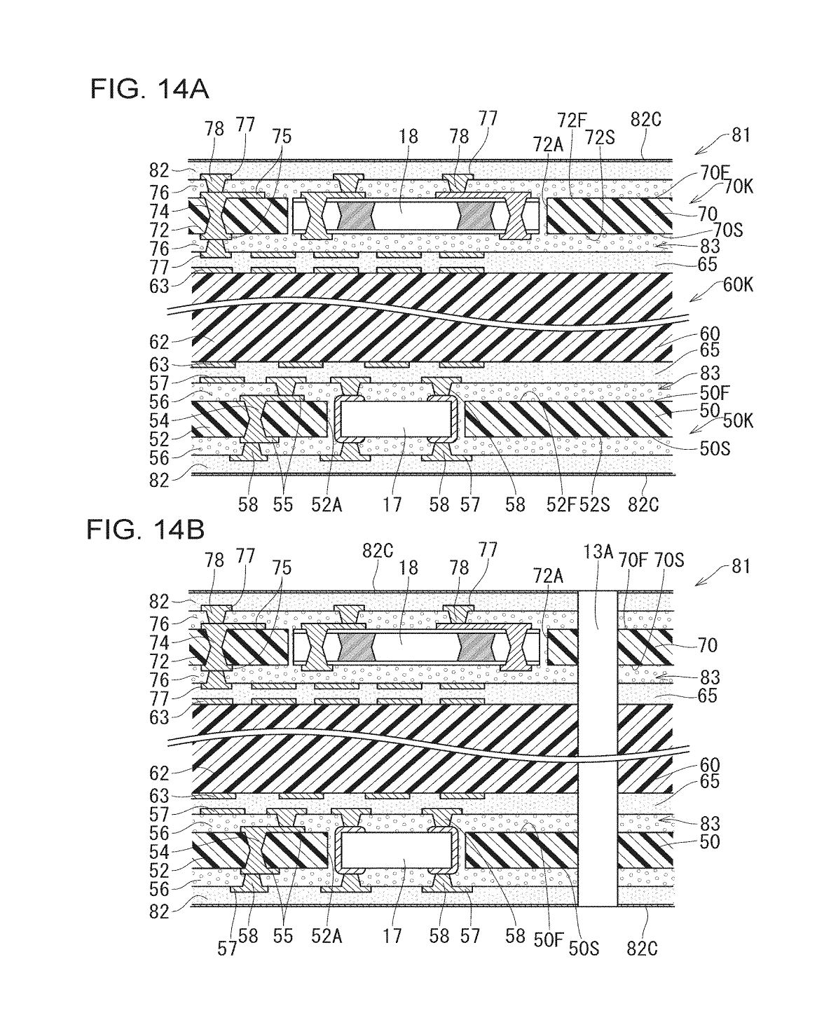

(3) Hot pressing is performed. The interlayer resin insulating layer 82 and the copper foil (82C) are laminated below the first intermediate base material (50K), and the second intermediate base material (60K) is laminated on the first intermediate base material (50K) via the adhesive layer 65. Further, the third intermediate base material (70K) is laminated on the second intermediate base material (60K) via the adhesive layer 65, and the interlayer resin insulating layer 82 and the copper foil (82C) are laminated on the third intermediate base material (70K) (see FIG. 14A). Then, a multilayer base material 81 is formed by laminating and integrating the first intermediate base material (50K), the second intermediate base material (60K) and the third intermediate base material (70K) in this order. In this case, the first core layer 50, the second core layer 60 and the third core layer 70 are respectively formed by the first insulating base material 52, the second insulating base material 62 and the third insulating base material 72; the F surface (52F) and the S surface (52S) of the first insulating base material 52 respectively become the F surface (50F) and the S surface (50S) of the first core layer 50; and the F surface (72F) and the S surface (72S) of the third insulating base material 72 respectively become the F surface (70F) and the S surface (70S) of the third core layer 70. Further, the inner side build-up part 83 positioned between the first core layer 50 and the second core layer 60 is formed by the interlayer resin insulating layer 56 and the conductor layer 57 on the F surface (50F) side of the first core layer 50; and the inner side build-up part 83 positioned between the second core layer 60 and the third core layer 70 is formed by the interlayer resin insulating layer 76 and the conductor layer 77 on the S surface (70S) side of the third core layer 70.

(4) A through hole (13A) penetrating the multilayer base material 81 is formed by router processing (see FIG. 14B). Further, a desmear treatment is performed in the through holes (13A).

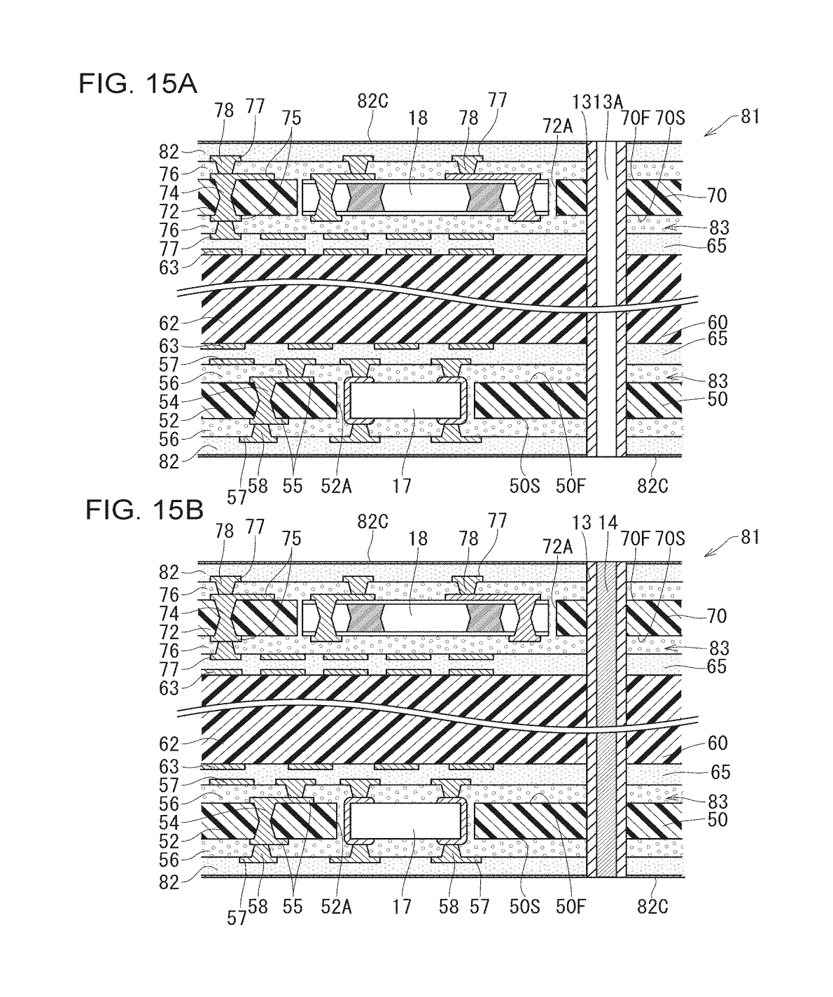

(5) An electroless plating treatment and an electrolytic plating treatment are performed. An electroless plating film and an electrolytic plating film (both are not illustrated in the drawings) are formed on the copper foil (82C), and a through-hole conductor 13 is formed by the electroless plating film and the electrolytic plating film formed on an inner wall of the through holes (13A) (see FIG. 15A).

(6) By screen printing, a filler 14 is filled in the through hole (13A) (specifically, in inner side of the through-hole conductors 13) (see FIG. 15B).

(7) Laser is irradiated from both front and back sides of the multilayer base material 81, and via holes (not illustrated in the drawings) are formed at predetermined positions in both front side and back side interlayer resin insulating layers 82.

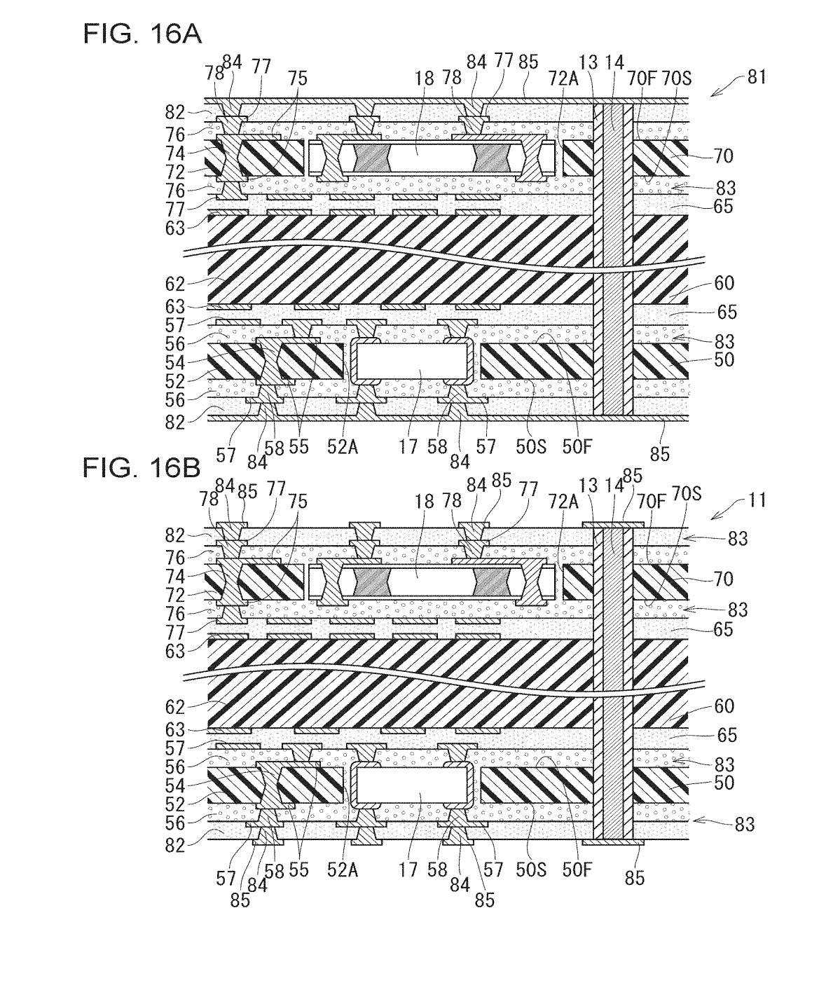

(8) An electroless plating treatment and an electrolytic plating treatment are performed in this order. As illustrated in FIG. 16A, the via conductors 84 are formed, and the conductor layers 85 are respectively formed on the interlayer resin insulating layers 82 from the copper foil (82C) and the plating films. In this case, the filler 14 filled in the through-hole conductor 13 is covered by the conductor layers 85, and the conductor layer 77 is connected to the conductor layer 85 via the via conductors 84.

(9) An etching resist of a predetermined pattern (not illustrated in the drawings) is formed on the plating films. Next, a portion of the conductor layers 85 where the etching resist is not formed is removed using an etching solution. A portion of the remaining conductor layers 85 covers the filler 14 of the through-hole conductor 13, and the other portion of the remaining conductor layers 85 is connected via the via conductors 84 to the conductor layers (57, 77) (see FIG. 16B). As a result, the core substrate 11 is formed. In this case, the inner side build-up part 83 positioned on the lower side of the first core layer 50 is formed by the interlayer resin insulating layers (56, 82) and the conductor layers 57, 87 on the S surface (50S) of the first core layer 50; and the inner side build-up part 83 positioned on the upper side of the third core layer 70 is formed by the interlayer resin insulating layers (76, 82) and the conductor layers (77, 85) on the F surface (70F) side of the third core layer 70.

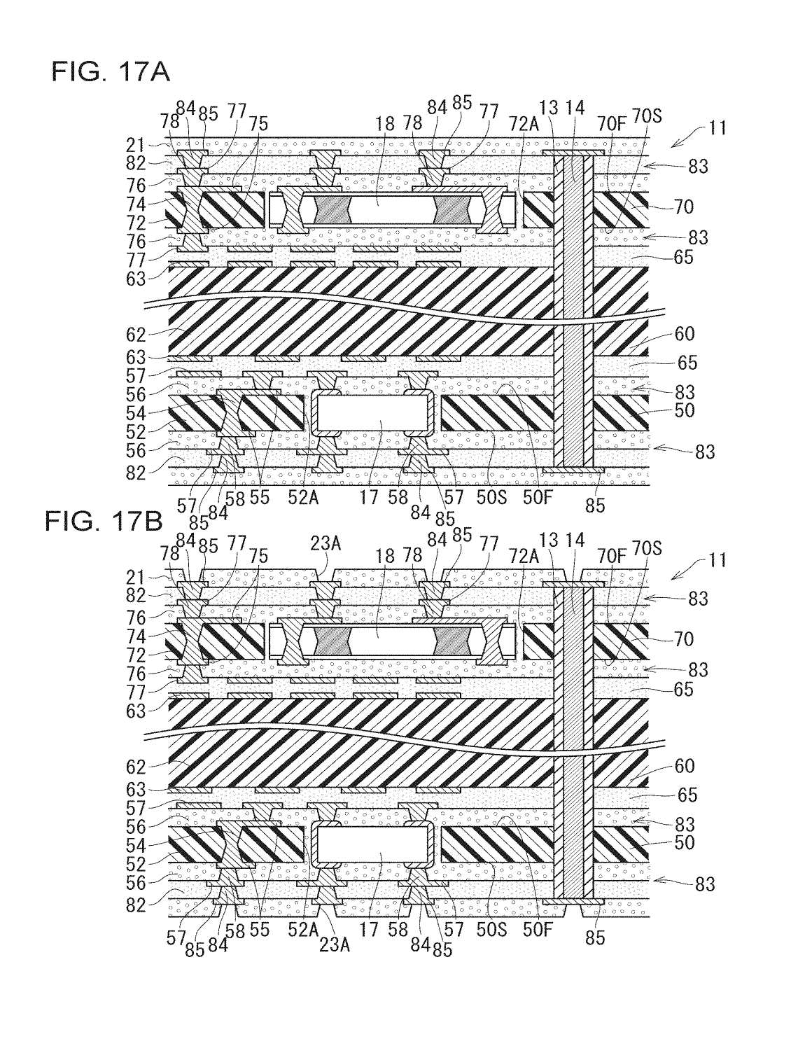

(10) An insulating film for a build-up substrate as an interlayer resin insulating layer 21 is laminated on both front side and back side surfaces of the core substrate 11 (see FIG. 17A). Next, laser is irradiated from both front and back sides of the core substrate 11, and via holes (23A) are formed at predetermined positions in the interlayer resin insulating layers 21 (see FIG. 17B).

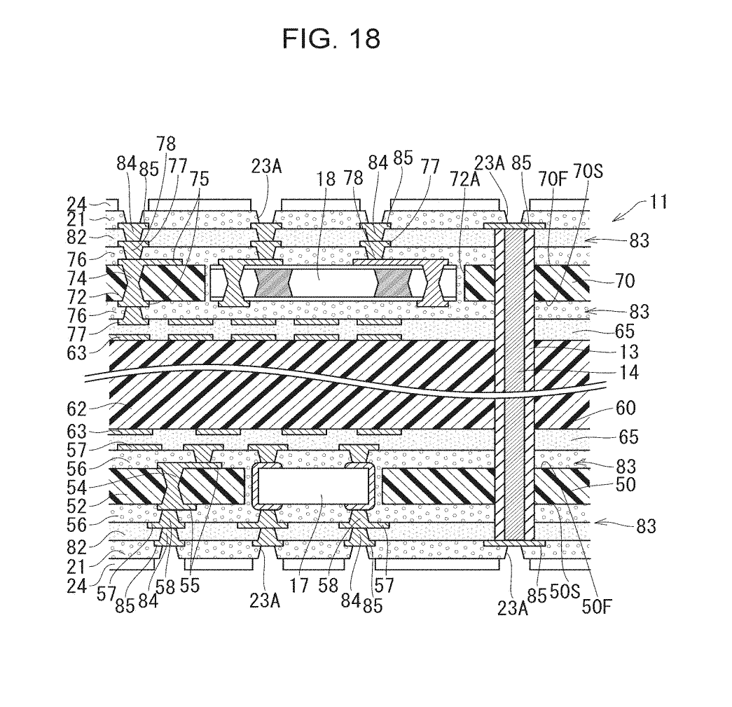

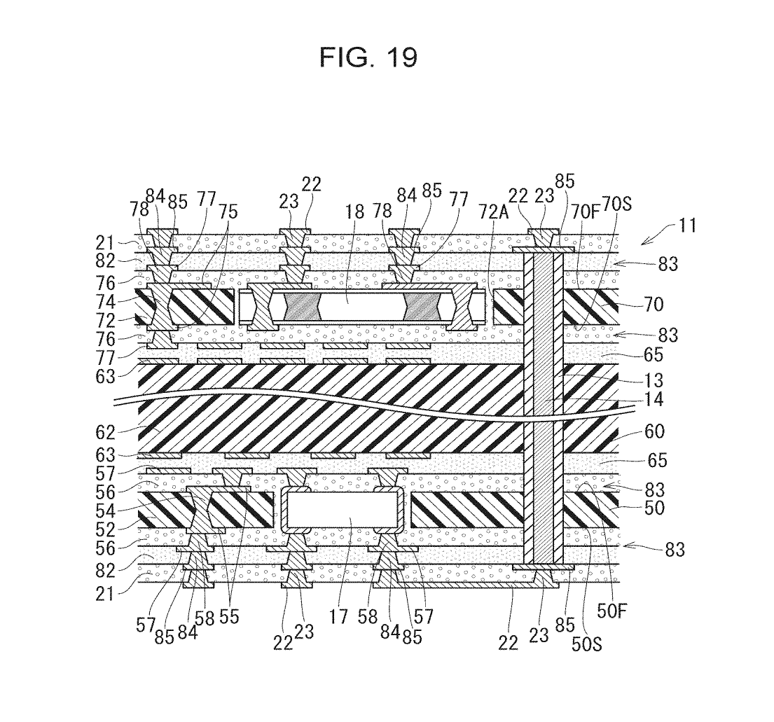

(11) A plating resist 24 of a predetermined pattern is formed on the interlayer resin insulating layers 21 (see FIG. 18). Next, an electrolytic plating treatment is performed. An electrolytic plating film is filled in the via holes (23A) and via conductors 23 are formed, and conductor layers 22 are formed in a non-forming portion of the plating resist (77R) (see FIG. 19).

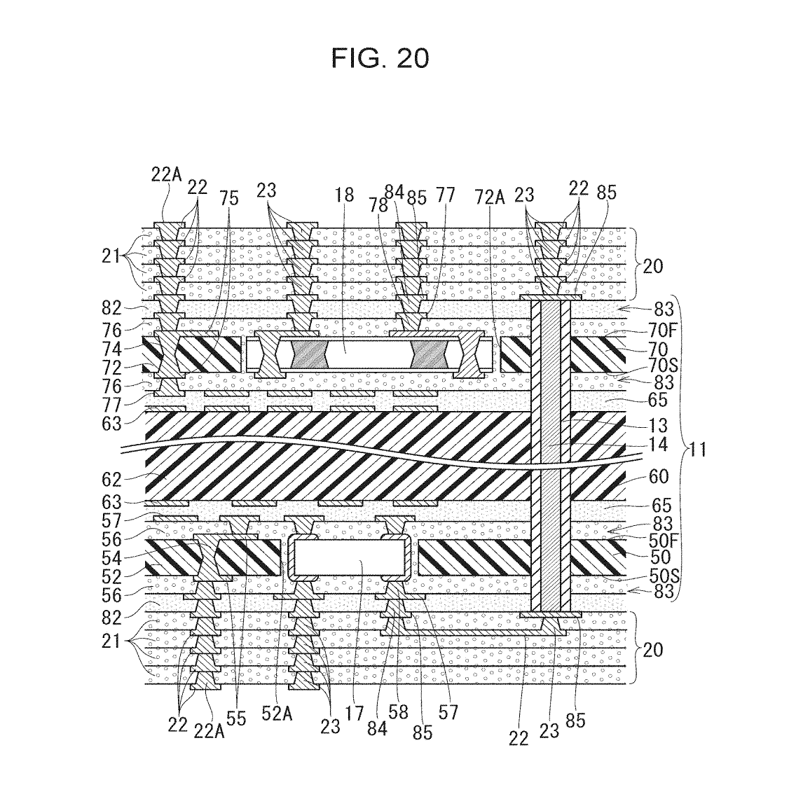

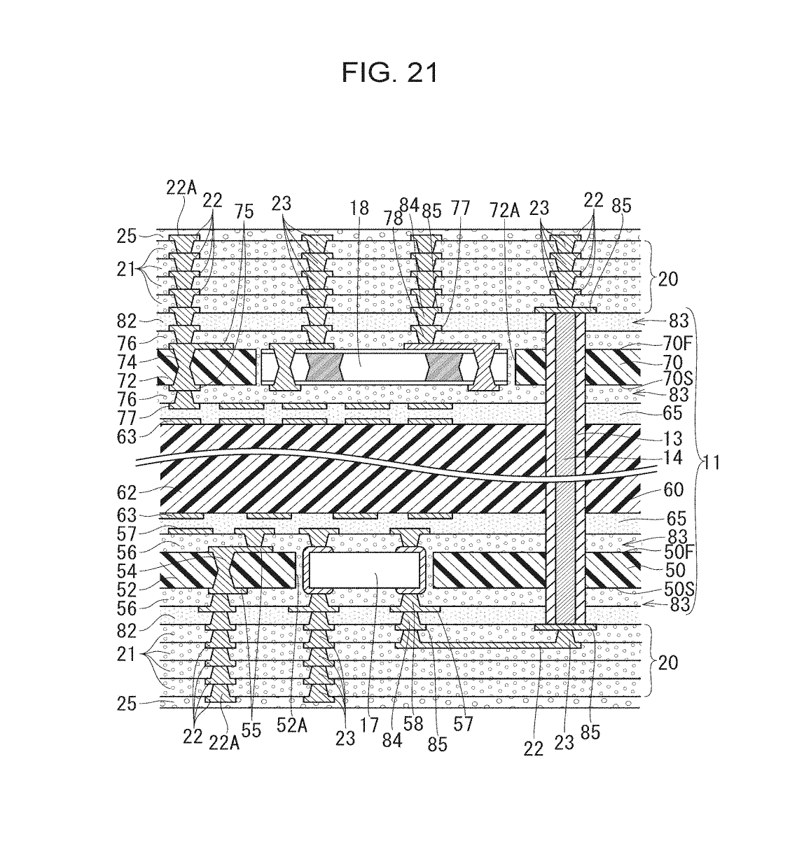

(12) The above-described processes (10) and (11) are repeated, and the outer side build-up parts 20, which are each formed by alternately laminating multiple interlayer resin insulating layers 21 and multiple conductor layers 22, are respectively formed on the front side and the back side of the core substrate 11 (see FIG. 20).

(13) A solder resist layer 25 is laminated on an outermost conductor layer (22A) formed on an outermost side (that is, a side farthest from the core substrate 11) of each of the outer side build-up parts 20.

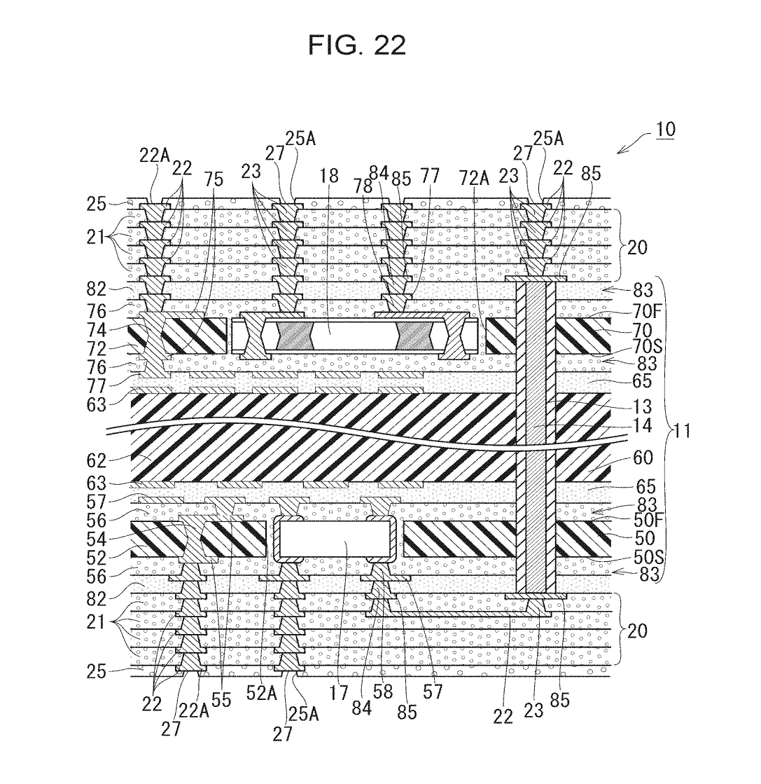

(14) Laser is irradiated from the front side and the back side of the core substrate 11 to predetermined positions in the solder resist layers 25, and the openings (25A) are formed in the solder resist layers 25 (see FIG. 22). Then, the pads 27 are formed by portions of the outermost conductor layers (22A) exposed by the openings (25A). As a result, the electronic component built-in substrate 10 illustrated in FIG. 2 is completed.

The description about the structure and the manufacturing method of the electronic component built-in substrate 10 of the present embodiment is as given above. Next, an operation effect of the electronic component built-in substrate 10 is described.

In the electronic component built-in substrate 10 of the present embodiment, the core substrate 11 has three core layers: the first core layer 50, the second core layer 60 and the third core layer 70, overlaid along the thickness direction. The capacitor components 17 or the inductor components 18 as electronic components are accommodated in the openings (52A, 72A) provided in the first core layer 50 and the third core layer 70 among the three core layers. In this way, in electronic component built-in substrate 10 of the present embodiment, the electronic components are accommodated in two core layers: the first core layer 50 and the third core layer 70. Therefore, as compared to the case where only one core layer is provided and electronic components are accommodated in the one core layer, the number of the built-in electronic components can be increased. In addition, in the present embodiment, the two core layers (the first core layer 50 and the third core layer 70) that accommodate electronic components are positioned to be stacked in the thickness direction of the electronic component built-in substrate 10. Therefore, reduction in rigidity of the electronic component built-in substrate 10 is suppressed.

Further, in the electronic component built-in substrate 10 of the present embodiment, in addition to the two core layers (the first core layer 50 and the third core layer 70) that accommodate electronic components, the second core layer 60 that does not have any opening is included. Therefore, as compared to a case where two core layers that accommodate electronic components are provided, reduction in rigidity of the core substrate 11 is suppressed and thus, reduction in rigidity of the electronic component built-in substrate 10 can be suppressed. In addition, the second core layer 60 has a higher rigidity than the first core layer 50 and the third core layer 70. Therefore, the rigidity of the electronic component built-in substrate 10 can be improved. Further, the second core layer 60 is positioned between the first core layer 50 and the third core layer 70. Therefore, well-balanced improvement in rigidity on both front side and back side of the electronic component built-in substrate 10 can be achieved.

Further, in the electronic component built-in substrate 10 of the present embodiment, the via conductors 58 are respectively connected to the front side electrodes and the back side electrodes of the electronic components (the capacitor component 17 and the inductor component 18) accommodated in the first core layer 50 and the third core layer 70. Therefore, as compared to a case where the via conductors 58 are only connected to electrodes on one side of the front and back sides, the electronic components can more satisfactorily operate.

### OTHER EMBODIMENTS

The present invention is not limited to the above-described embodiment. For example, embodiments described below are also included in the technical scope of the present invention. Further, in addition to the embodiments described below, the present invention can also be embodied in various modified forms within the scope without departing from the spirit of the present invention.

(1) In the above embodiment, the capacitor component 17 and the inductor component 18 are used as examples of the “electronic components” according to an embodiment of the present invention. However, for example, examples of the “electronic components” may also include interposers, resistors, and the like. The “electronic components” according to an embodiment of the present invention are not limited to passive components, but may also be active components.

(2) In the embodiment, an example is described in which the inner side build-up parts 83 are each formed from one or two interlayer resin insulating layers and one or two conductor layers. However, it is also possible that the inner side build-up parts 83 are each formed from three or more interlayer resin insulating layers and three or more conductor layers.

(3) In the above embodiment, the via conductors 58 are respectively connected to the front side electrodes and the back side electrodes of the electronic components (the capacitor component 17 and the inductor component 18) accommodated in the first core layer 50 and the third core layer 70. However, it is also possible that the via conductors 58 are only connected to the back side electrodes of an electronic component accommodated in the first core layer 50, and the via conductors 58 are only connected to the front side electrodes of an electronic component accommodated in the third core layer 70.

In an electronic component built-in substrate, when the number of openings penetrating the core substrate is increased in order to increase the number of built-in electronic components, there is likely a problem that the rigidity of the electronic component built-in substrate is decreased.

An electronic component built-in substrate according to an embodiment of the present invention is capable of suppressing reduction in rigidity while allowing the number of built-in electronic components to increase, and another embodiment of the present invention provides a method for manufacturing such an electronic component built-in substrate.

According to one aspect of the present invention, an electronic component built-in substrate includes: a first core layer that has an opening and accommodates an electronic component in the opening; a second core layer that is positioned on a front side of the first core layer; a third core layer that is positioned on a front side of the second core layer and has an opening and accommodates an electronic component in the opening; and outer side build-up parts that each include multiple conductor layers and multiple interlayer resin insulating layers and are respectively positioned on a back side of the first core layer and a front side of the third core layer. The second core layer has a higher rigidity than the first core layer and the third core layer.

Obviously, numerous modifications and variations of the present invention are possible in light of the above teachings. It is therefore to be understood that within the scope of the appended claims, the invention may be practiced otherwise than as specifically described herein.

1. An electronic component built-in substrate, comprising:
a first core layer having an opening portion;
a second core layer formed on the first core layer;
a third core layer formed on the second core layer and having an opening portion;
a first electronic component accommodated in the opening portion of the first core layer;
a second electronic component accommodated in the opening portion of the third core layer;
a first outer side build-up structure formed on the first core layer on an opposite side with respect to the second core layer such that the first outer side build-up structure comprises a plurality of conductor layers and a plurality of interlayer resin insulating layers; and
a second outer side build-up structure formed on the third core layer on an opposite side with respect to the second core layer such that the second outer side build-up structure comprises a plurality of conductor layers and a plurality of interlayer resin insulating layers,
wherein the second core layer has a rigidity which is higher than a rigidity of the first core layer and a rigidity of the third core layer.

2. An electronic component built-in substrate according to claim 1, wherein the first, second and third core layers are formed such that the second core layer has a thickness which is 1.5 or more times larger than a thickness of the first core layer and a thickness of the third core layer.

3. An electronic component built-in substrate according to claim 1, further comprising:
a first inner side build-up structure formed between the first core layer and the first outer side build-up structure such that the first inner side build-up structure comprises a conductor layer and an interlayer resin insulating layer;
a second inner side build-up structure formed between the first core layer and the second core layer such that the second inner side build-up structure comprises a conductor layer and an interlayer resin insulating layer;
a third inner side build-up structure formed between the second core layer and the third core layer such that the third inner side build-up structure comprises a conductor layer and an interlayer resin insulating layer; and
a fourth inner side build-up structure formed between the third core layer and the second outer side build-up structure such that the fourth inner side build-up structure comprises a conductor layer and an interlayer resin insulating layer.

4. An electronic component built-in substrate according to claim 3, wherein the first inner side build-up structure is formed such that the first inner side build-up structure comprises a via conductor structure formed in the interlayer resin insulating layer of the first inner side build-up structure and connected to an electrode structure of the first electronic component in the first core layer, and the fourth inner side build-up structure is formed such that the fourth inner side build-up structure comprises a via conductor structure formed in the interlayer resin insulating layer of the fourth inner side build-up structure and connected to an electrode structure of the second electronic component in the third core layer.

5. An electronic component built-in substrate according to claim 4, wherein the second inner side build-up structure is formed such that the second inner side build-up structure comprises a via conductor structure formed in the interlayer resin insulating layer of the second inner side build-up structure and connected to an electrode structure of the first electronic component in the first core layer, and the third inner side build-up structure is formed such that the third inner side build-up structure comprises a via conductor structure formed in the interlayer resin insulating layer of the third inner side build-up structure and connected to an electrode structure of the second electronic component in the third core layer.

6. An electronic component built-in substrate according to claim 3, wherein each of the first, second, third and fourth inner side build-up structures are formed such that each of the interlayer resin insulating layers in the first, second, third and fourth inner side build-up structures comprises a thermosetting insulating resin material and an inorganic filler material.

7. An electronic component built-in substrate according to claim 1, further comprising;
a first adhesive layer formed between the first and second core layers such that the first and second core layers are bonded through the first adhesive layer; and
a second adhesive layer formed between the second and third core layers such that the second and third core layers are bonded through the second adhesive layer.

8. An electronic component built-in substrate according to claim 7, wherein each of the first and second adhesive layers comprises a core material and a resin material.

9. An electronic component built-in substrate according to claim 1, wherein the first and second outer side build-up structures are formed such that each of the interlayer resin insulating layers in the first and second outer side build-up structures comprises a thermosetting resin material and an inorganic filler material.

10. An electronic component built-in substrate according to claim 2, further comprising:
a first inner side build-up structure formed between the first core layer and the first outer side build-up structure such that the first inner side build-up structure comprises a conductor layer and an interlayer resin insulating layer;
a second inner side build-up structure formed between the first core layer and the second core layer such that the second inner side build-up structure comprises a conductor layer and an interlayer resin insulating layer;
a third inner side build-up structure formed between the second core layer and the third core layer such that the third inner side build-up structure comprises a conductor layer and an interlayer resin insulating layer; and
a fourth inner side build-up structure formed between the third core layer and the second outer side build-up structure such that the fourth inner side build-up structure comprises a conductor layer and an interlayer resin insulating layer.

11. An electronic component built-in substrate according to claim 10, wherein the first inner side build-up structure is formed such that the first inner side build-up structure comprises a via conductor structure formed in the interlayer resin insulating layer of the first inner side build-up structure and connected to an electrode structure of the first electronic component in the first core layer, and the fourth inner side build-up structure is formed such that the fourth inner side build-up structure comprises a via conductor structure formed in the interlayer resin insulating layer of the fourth inner side build-up structure and connected to an electrode structure of the second electronic component in the third core layer.

12. An electronic component built-in substrate according to claim 11, wherein the second inner side build-up structure is formed such that the second inner side build-up structure comprises a via conductor structure formed in the interlayer resin insulating layer of the second inner side build-up structure and connected to an electrode structure of the first electronic component in the first core layer, and the third inner side build-up structure is formed such that the third inner side build-up structure comprises a via conductor structure formed in the interlayer resin insulating layer of the third inner side build-up structure and connected to an electrode structure of the second electronic component in the third core layer.

13. An electronic component built-in substrate according to claim 4, wherein each of the first, second, third and fourth inner side build-up structures are formed such that each of the interlayer resin insulating layers in the first, second, third and fourth inner side build-up structures comprises a thermosetting insulating resin material and an inorganic filler material.

14. An electronic component built-in substrate according to claim 2, further comprising;
a first adhesive layer formed between the first and second core layers such that the first and second core layers are bonded through the first adhesive layer; and
a second adhesive layer formed between the second and third core layers such that the second and third core layers are bonded through the second adhesive layer.

15. An electronic component built-in substrate according to claim 14, wherein each of the first and second adhesive layers comprises a core material and a resin material.

16. An electronic component built-in substrate according to claim 2, wherein the first and second outer side build-up structures are formed such that each of the interlayer resin insulating layers in the first and second outer side build-up structures comprises a thermosetting resin material and an inorganic filler material.

17. An electronic component built-in substrate according to claim 5, wherein each of the first, second, third and fourth inner side build-up structures are formed such that each of the interlayer resin insulating layers in the first, second, third and fourth inner side build-up structures comprises a thermosetting insulating resin material and an inorganic filler material.

18. An electronic component built-in substrate according to claim 3, further comprising;
a first adhesive layer formed between the first and second core layers such that the first and second core layers are bonded through the first adhesive layer; and
a second adhesive layer formed between the second and third core layers such that the second and third core layers are bonded through the second adhesive layer.

19. An electronic component built-in substrate according to claim 18, wherein each of the first and second adhesive layers comprises a core material and a resin material.

20. A method for manufacturing an electronic component built-in substrate, comprising:
preparing a first intermediate base material comprising a first core layer;
preparing a second intermediate base material comprising a second core layer;
preparing a third intermediate base material comprising a third core layer;
bonding the first, second and third intermediate base materials such that the first, second and third intermediate base materials form a laminated structure adhered through an adhesive layer formed between the first and second intermediate base materials and an adhesive layer formed between the second and third intermediate base materials;
forming a first outer side build-up structure on the first core layer on an opposite side with respect to the second core layer such that the first outer side build-up structure comprises a plurality of conductor layers and a plurality of interlayer resin insulating layers; and
forming a second outer side build-up structure on the third core layer on an opposite side with respect to the second core layer such that the second outer side build-up structure comprises a plurality of conductor layers and a plurality of interlayer resin insulating layers,
wherein the first intermediate base material comprises the first core layer, a first electronic component accommodated in an opening portion of the first core layer, a plurality of conductor layers formed on front and back surfaces of the first core layer respectively, a plurality of interlayer resin insulating layers formed on the front and back surfaces of the first core layer respectively, and a plurality of via conductor structures formed in the interlayer resin insulating layers and connected to a plurality of electrode structures of the first electronic component respectively, the third intermediate base material comprises the third core layer, a second electronic component accommodated in an opening portion of the third core layer, a plurality of conductor layers formed on front and back surfaces of the third core layer respectively, a plurality of interlayer resin insulating layers formed on the front and back surfaces of the third core layer respectively, and a plurality of via conductor structures formed in the interlayer resin insulating layers and connected to a plurality of electrode structures of the second electronic component respectively, and the second core layer has a rigidity which is higher than a rigidity of the first core layer and a rigidity of the third core layer.
